(19) United States
(12) Patent Application Publication
(10) Pub. No.: US 2026/0047025 A1
(43) Pub. Date: Feb. 12, 2026

(54) LOCKING MECHANISM AND ELECTRONIC DEVICE INCLUDING THE SAME

(71) Applicant: Jabil Circuit (Singapore) Pte. Ltd., Singapore (SG)

(72) Inventors: Kuo-Jui Mei, Taichung City (TW); Jen-Chieh Kuo, Taichung City (TW); Tai-Yi Chiang, Taichung City (TW)

(73) Assignee: Jabil Circuit (Singapore) Pte. Ltd., Singapore (SG)

(21) Appl. No.: 19/272,684

(22) Filed: Jul. 17, 2025

(30) Foreign Application Priority Data
Aug. 12, 2024 (CN) 202421943014.2

(51) Int. Cl. H05K 7/14

(52) U.S. Cl. CPC H05K 7/1417; H05K 7/1409; H05K 7/1415

(57) ABSTRACT

A locking mechanism for removably locking a first electronic component to a second electronic component includes a positioning post, a locking member, and a biasing member. The positioning post is adapted to be mounted on the second electronic component and has a neck. The locking member is adapted to be movably connected to the first electronic component, and includes an engaging portion and a trigger portion. The biasing member is disposed for biasing the locking member to retain the locking member in a locking position where the engaging portion is engaged with the neck. The trigger portion of the locking member is operable for driving the locking member to move away from the locking position to disengage the engaging portion from the neck and to deform the biasing member.

### CROSS-REFERENCE TO RELATED APPLICATION

This application claims priority to Chinese Patent Application No. 202421943014.2, filed on Aug. 12, 2024, the entire disclosure of which is incorporated by reference herein.

### FIELD

The disclosure relates to a locking mechanism for an electronic device, and more particularly to a locking mechanism for removably locking electronic components of the electronic device.

### BACKGROUND

An expansion card module of an electronic device is locked onto a main board by a locking mechanism, thereby retaining the expansion card on the main board. The conventional locking mechanism has a large number of components, so the conventional locking mechanism is inconvenient to assemble, is bulky, is space-inefficient, and is costly to manufacture. Moreover, locking and unlocking processes of the locking mechanism involve many steps, so the locking and unlocking processes are slow, time-consuming, and not easy to operate.

### SUMMARY

Therefore, an object of the disclosure is to provide a locking mechanism that can alleviate at least one of the drawbacks of the prior art.

According to the disclosure, the locking mechanism for removably locking a first electronic component to a second electronic component includes a positioning post, a locking member, and a biasing member. The positioning post is adapted to be mounted on the second electronic component and has a neck. The locking member is adapted to be movably connected to the first electronic component, and includes an engaging portion and a trigger portion. The biasing member is disposed for biasing the locking member to retain the locking member in a locking position where the engaging portion is engaged with the neck. The trigger portion of the locking member is operable for driving the locking member to move away from the locking position to disengage the engaging portion from the neck and to deform the biasing member.

Another object of the disclosure is to provide an electronic device that can alleviate at least one of the drawbacks of the prior art.

According to the disclosure, the electronic device includes a first electronic component, a second electronic component, and a locking mechanism as described above for removably locking the first electronic component to the second electronic component.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a fragmentary perspective view illustrating an embodiment of an electronic device according to the disclosure.

FIG. 2 is a fragmentary exploded perspective view illustrating an embodiment of a locking mechanism, a first electronic component, and a second electronic component according to the disclosure.

FIG. 3 is a fragmentary exploded perspective view of the locking mechanism.

FIG. 4 is a fragmentary exploded perspective view similar to FIG. 3 but taken from another angle.

FIG. 5 is a perspective view illustrating a locking member of the locking mechanism.

FIG. 6 is a fragmentary sectional view of the embodiment of the electronic device.

FIG. 7 is a fragmentary sectional view of the embodiment of the electronic device.

FIG. 8 is a fragmentary sectional view of the embodiment of the electronic device, illustrating that the locking member is in a locking position.

FIG. 9 is a fragmentary sectional view of the embodiment of the electronic device, illustrating that the locking member is in an unlocking position.

FIG. 10 is a fragmentary sectional view of the embodiment of the electronic device.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

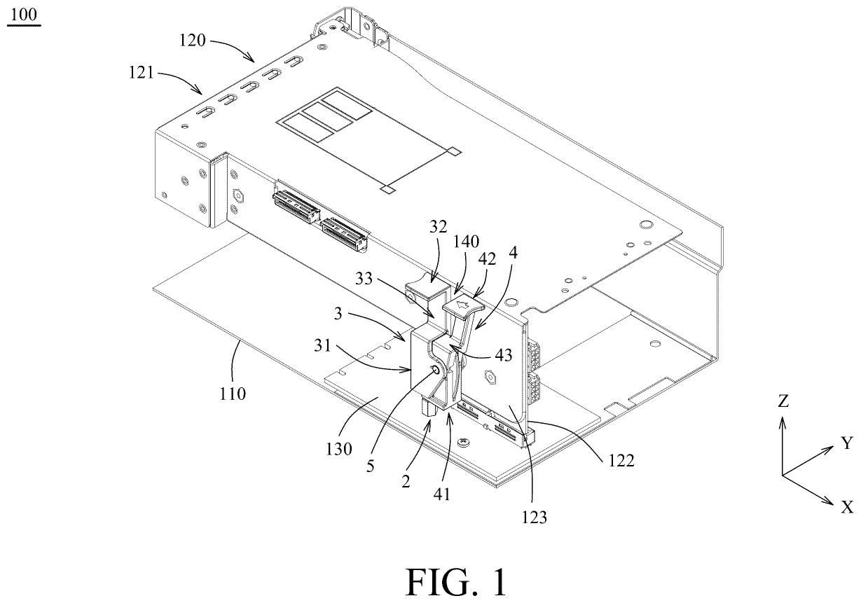

Referring to FIG. 1, an embodiment of an electronic device 100 according to the disclosure includes a housing 110, a first electronic component 120, a second electronic component 130, and a locking mechanism 140.

A first horizontal direction (X), a second horizontal direction (Y) perpendicular to the first horizontal direction (X), and a vertical direction (Z) perpendicular to both the first horizontal direction (X) and the second horizontal direction (Y) of the electronic device 100 are defined for facilitating the following description. For example, the first horizontal direction (X) is a front-rear direction, where the arrow in FIG. 1 indicates the front-side; the second horizontal direction (Y) is a left-right direction, where the arrow in FIG. 1 indicates the left-side; and the vertical direction (Z) is an up-down direction, where the arrow in FIG. 1 indicates the upward-side.

The electronic device 100 is exemplified by a 2U server but is not limited thereto, and the electronic device 100 may also be a computer or a storage device. The first electronic component 120 includes a frame 121, a connectable circuit board 122, and two expansion cards (not shown). The frame 121 has a side plate 123 that is in a standing state. The connectable circuit board 122 is disposed on an inner side of the side plate 123. The expansion cards are electrically connected to the connectable circuit board 122. The second electronic component 130 is exemplified by a motherboard disposed in the housing 110, but is not limited thereto. The second electronic component 130 allows the connectable circuit board 122 to connect thereto. The locking mechanism 140 is adapted to lock the first electronic component 120 onto the second electronic component 130.

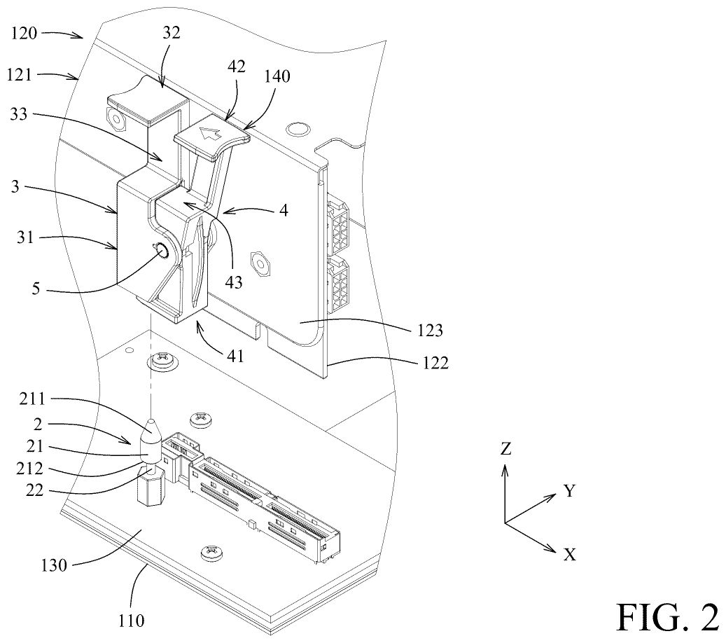

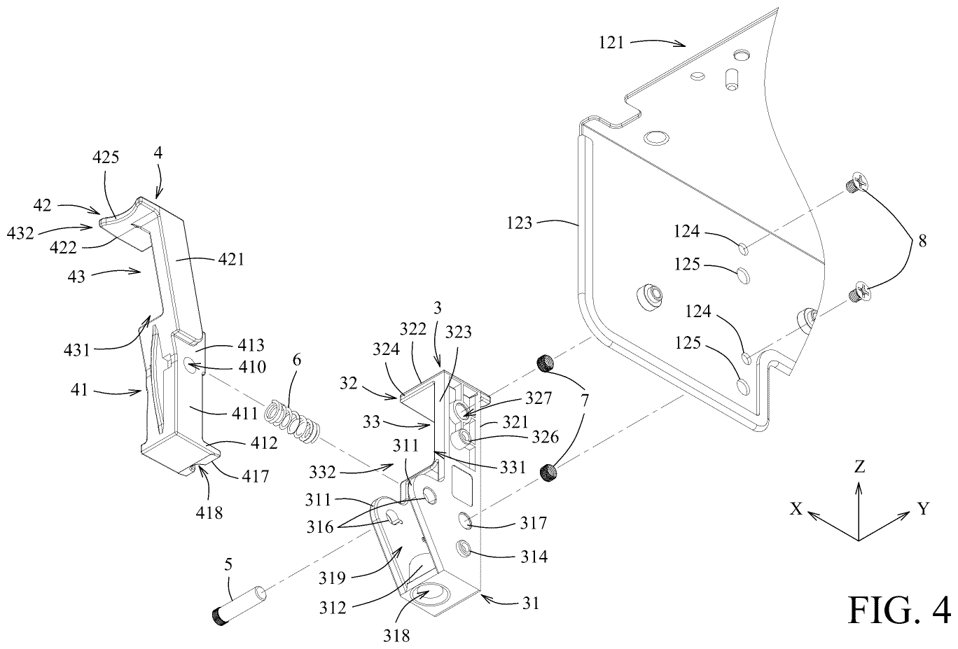

Referring to FIGS. 2, 3, and 4, the side plate 123 of the frame 121 of the first electronic component 120 is formed with two through holes 124 that are spaced apart from each other in the vertical direction (Z), and two positioning holes 125 that are spaced apart from each other in the vertical direction (Z).

The locking mechanism 140 includes a positioning post 2, an abutment member 3, a locking member 4, a shaft 5, a biasing member 6, two nuts 7, and two screws 8. The positioning post 2 is mounted on the second electronic component 130, and has a head 21 and a neck 22 that is connected to a bottom end of the head 21. The head 21 is in the form of a cylinder, and has an outer taper end surface 211 that is tapered upwardly, and an annular lower surface 212 that is opposite to the outer taper end surface 211 and that faces downwardly. The neck 22 is in the form of a cylinder, and has an outer diameter smaller than that of the head 21.

The abutment member 3 is adapted to be mounted on the first electronic component 120, and, for example, is configured as a single component integrally formed from a plastic material by an injection molding process. The abutment member 3 includes a sleeve shell 31 that is sleeved removably on the positioning post 2, and a handle rod 32 that protrudes from a top end of the sleeve shell 31. The sleeve shell 31 has an end wall 310, two side walls 311, a sleeve 312, a top wall 313, a positioning post 314, and a support pillar 315. The side walls 311 respectively extend in the first horizontal direction (X) from opposite sides of the end wall 310, and are spaced apart from each other in the second horizontal direction (Y). Each of the side walls 311 is formed with a shaft hole 316 that receives the shaft 5. One of the side walls 311 is adapted to abut against an outer side of the side plate 123, and is formed with a receiving hole 317 that is adapted to correspond in position to one of the through holes 124. The sleeve 312 is disposed between the side walls 311, and is adjacent to a bottom end of the end wall 310 and bottom ends of the side walls 311. The sleeve 312 is mounted on the head 21 of the positioning post 2, and is formed with a limiting hole 318 extending in the vertical direction (Z) for receiving the head 21. The top wall 313 is connected to a top end of the end wall 310 and top ends of the side walls 311. The end wall 310, the side walls 311, the sleeve 312, and the top wall 313 cooperatively define an accommodating space 319 that opens forward in the first horizontal direction (X). The positioning post 314 protrudes from an outer side of the one of the side walls 311, and is adapted to be inserted in and engaged with one of the positioning holes 125. The support pillar 315 extends from the end wall 310 and is located within the accommodating space 319.

The handle rod 32 has an upright portion 321 and a transverse portion 322. The upright portion 321 protrudes from a top end of the top wall 313. The transverse portion 322 protrudes transversely from a top end of the upright portion 321, such that the handle rod 32 is inverted L-shaped. The handle rod 32 and the sleeve shell 31 cooperatively define a first wiring channel 33 that allows at least one wire (not shown) to extend therethrough. In this embodiment, the first wiring channel 33 extends in the first horizontal direction (X). The upright portion 321 of the handle rod 32 is adjacent to a lateral side of the sleeve shell 31. To be more specific, the upright portion 321 of the handle rod 32 is adjacent to the one of the side walls 311, and is adapted to abut against the side plate 123, so as to maximize the size of the first wiring channel 33, thereby allowing more wires to extend through the first wiring channel 33. The first wiring channel 33 has two first end openings 331 opposite to each other in the first horizontal direction (X), and a first side opening 332 located between the first end openings 331. The first end openings 331 allow the at least one wire to extend therethrough, and the first side opening 332 allows the at least one wire to pass therethrough, thereby facilitating installation or removal of the at least one wire. In addition, the upright portion 321 has an upright abutment surface 323. The transverse portion 322 has a transverse abutment surface 324 that is connected to the upright abutment surface 323, and a first force-receiving surface 325 that is opposite to the transverse abutment surface 324. The first force-receiving surface 325 is configured to be pressed by a user's finger during operation. The handle rod 32 further has a positioning post 326 that protrudes from an outer side of the upright portion 321 for engaging with one of the positioning holes 125. The upright portion 321 has a receiving hole 327 that is adapted to correspond in position to another one of the through holes 124.

Each of the nuts 7 is fixedly disposed in a corresponding one of the receiving holes 317, 327. Each of the screws 8 is inserted into a corresponding one of the through holes 124 and screwed into a corresponding one of the nuts 7, such that the abutment member 3 is locked to the side plate 123.

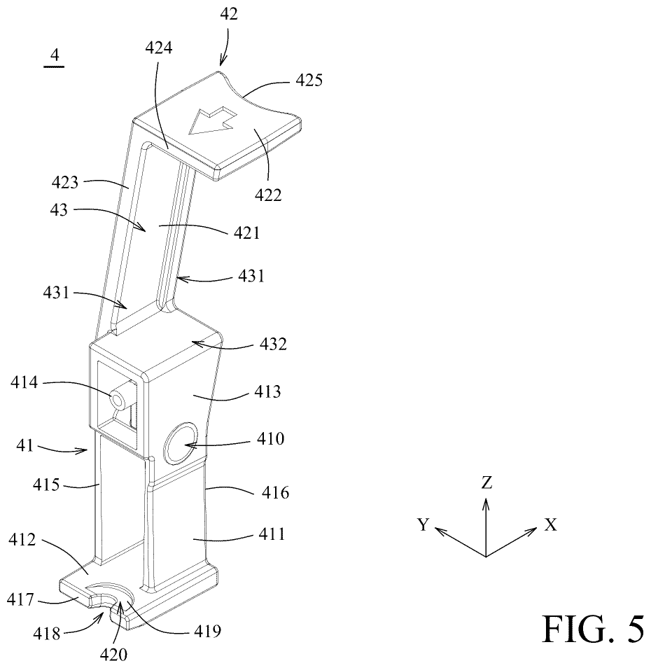

Referring to FIGS. 2, 3, 4, and 5, the locking member 4 is movably connected to the frame 121 of the first electronic component 120 to lock the first electronic component 120 onto the positioning post 2, thereby locking the first electronic component 120 onto the second electronic component 130. The shaft 5 is mounted to the abutment member 3 and the locking member 4, such that the locking member 4 is connected to the abutment member 3, and such that the locking member 4 is pivotable about the shaft 5 relative to the abutment member 3. In this embodiment, the locking member 4 is rotatably connected to the shaft 5, such that the locking member 4 is pivotably connected to the frame 121 of the first electronic component 120 through the abutment member 3 and the shaft 5.

The locking member 4 is configured as a single component integrally formed from a plastic material by an injection molding process, and includes a retaining rod 41 and an operating lever 42. The retaining rod 41 is pivotably connected to the sleeve shell 31 via the shaft 5 and is received in the accommodating space 319. The retaining rod 41 is formed with a pivot hole 410 for receiving the shaft 5, and includes a lower rod body 411, an engaging portion 412, an upper rod body 413, and a support pillar 414. The lower rod body 411 is located below the pivot hole 410, and has a first end 415 facing the abutment member 3, and a second end 416 opposite to the first end 415. The first end 415 and the second end 416 are spaced apart from each other in the first horizontal direction (X). The engaging portion 412 is plate-shaped, extends from a bottom end of the lower rod body 411, and is located below the shaft 5. Particularly, the engaging portion 412 is configured to protrude rearwardly from the first end 415 of the lower rod body 411 in the first horizontal direction (X), and has a free end 417 that is spaced apart from the first end 415. The engaging portion 412 is formed with an engaging slot 418 that is recessed from the free end 417 toward the first end 415 to receive the neck 22 such that the engaging portion 412 is engaged with the neck 22. The engaging portion 412 has a beveled surface 419 that is formed on a top surface thereof around the engaging slot 418. The beveled surface 419 is semi-circular in shape, and is inclined downwardly toward the first end 415 to define a semi-circular beveled groove 420 that communicates with the engaging slot 418. The beveled surface 419 is configured for abutting against the annular lower surface 212 of the head 21 in a surface-contact manner. The semi-circular beveled groove 420 is configured for accommodating a part of the bottom end of the head 21 of the positioning post 2. The upper rod body 413 is connected to a top end of the lower rod body 411 and is located above the pivot hole 410. The upper rod body 413 is hollow, and the support pillar 414 is disposed inside the upper rod body 413.

The operating lever 42 extends obliquely relative to the handle rod 32, and has an inclined portion 421 and a trigger portion 422. The inclined portion 421 protrudes from a top end of the upper rod body 413 of the retaining rod 41. The trigger portion 422 is plate-shaped, protrudes transversely from a top end of the inclined portion 421, and is located above the shaft 5. The operating lever 42 and the retaining rod 41 cooperatively define a second wiring channel 43 that allows at least one wire (not shown) to extend therethrough. In this embodiment, the second wiring channel 43 extends in the first horizontal direction (X). The second wiring channel 43 and the first wiring channel 33 are arranged to correspond in position to each other in the first horizontal direction (X). The operating lever 42 is inverted L-shaped. The inclined portion 421 of the operating lever 42 is adjacent to a lateral side of the upper rod body 413 of the retaining rod 41. The inclined portion 421 of the operating lever 42 protrudes from the lateral side of the upper rod body 413 of the retaining rod 41 so as to correspond in position to the upright portion 321 of the handle rod 32, thereby maximizing the size of the second wiring channel 43 and allowing more wires to extend therethrough. The second wiring channel 43 has two second end openings 431 opposite to each other in the first horizontal direction (X), and a second side opening 432 located between the second end openings 431. The second end openings 431 allow the at least one wire to extend therethrough, and the second side opening 432 allows the at least one wire to pass therethrough, thereby facilitating installation or removal of the at least one wire. In addition, the inclined portion 421 has a first inclined abutment surface 423 for abutting against the vertical abutment surface 323. The trigger portion 422 has a second inclined abutment surface 424 for abutting against the horizontal abutment surface 324, and a second force-receiving surface 425 that is opposite to the second inclined abutment surface 424. The second force-receiving surface 425 is configured to be pressed by the user's finger during operation.

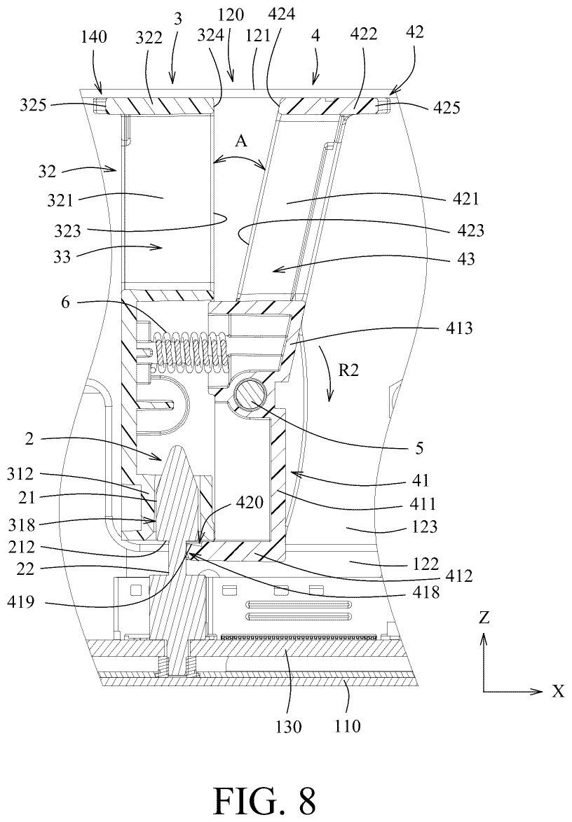

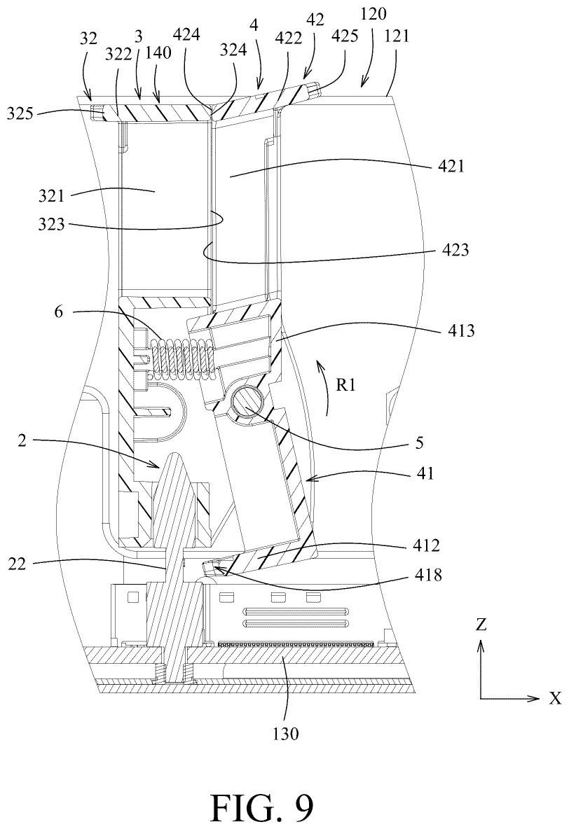

The locking member 4 is pivotable about the shaft 5 relative to the abutment member 3 between a locking position (as shown in FIG. 8), where the engaging portion 412 of the locking member 4 is engaged with the neck 22 of the positioning post 2, and an unlocking position (as shown in FIG. 9), where the engaging portion 412 of the locking member 4 is disengaged from the neck 22 of the positioning post 2. The second force-receiving surface 425 of the trigger portion 422 is operable by the user's finger for driving the locking member 4 to move away from the locking position to the unlocking position, thereby disengaging the engaging portion 412 from the neck 22 of the positioning post 2.

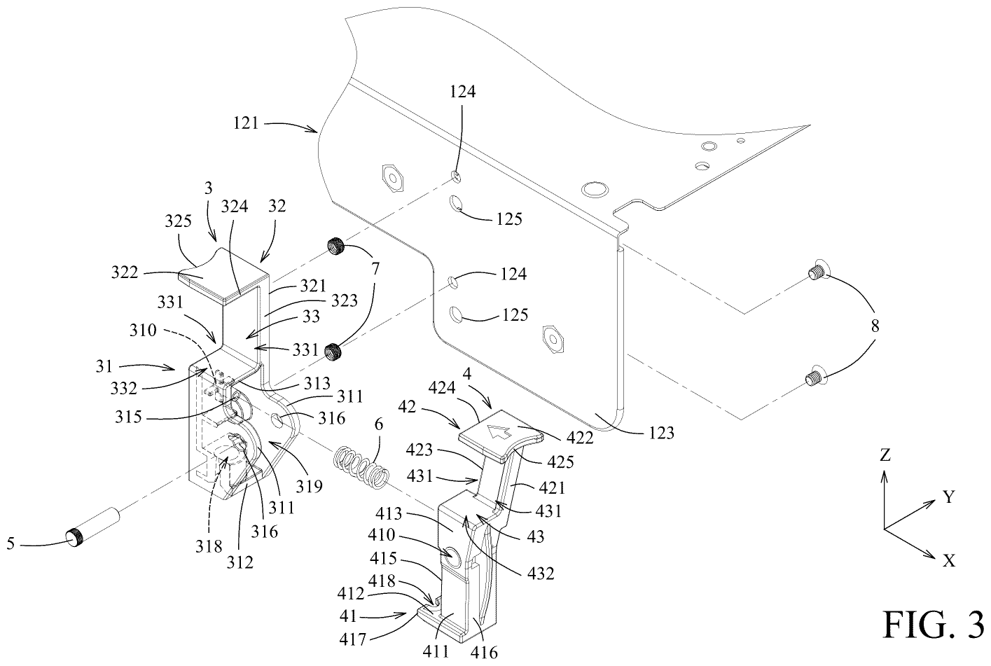

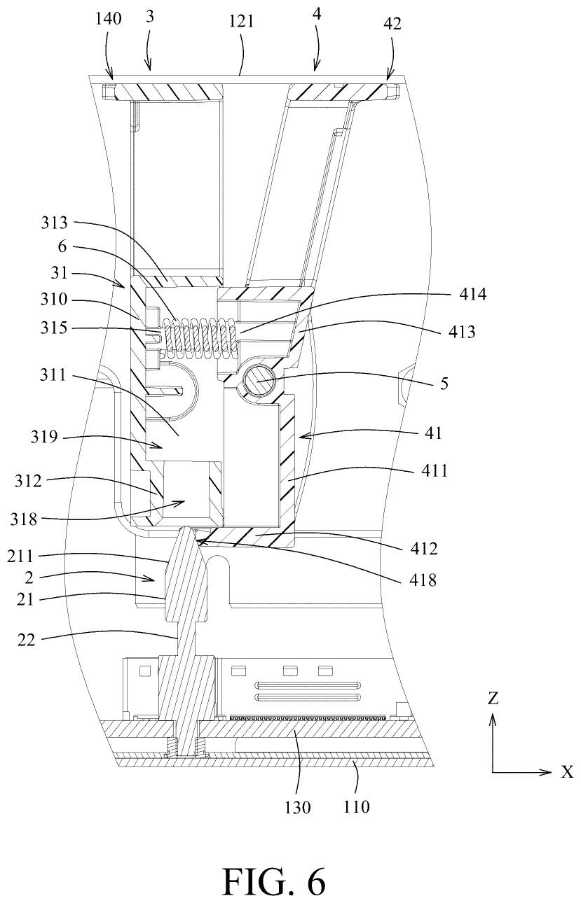

Referring to FIGS. 3, 4, and 6, the biasing member 6 is disposed between the abutment member 3 and the locking member 4 for biasing the locking member 4 to retain the locking member 4 in the locking position. On the other hand, when the second force-receiving surface 425 of the trigger portion 422 is operated by the user and the locking member 4 is driven to move away from the locking position to the unlocking position, the biasing member 6 is pressed by the locking member 4 and is deformed. In this embodiment, the biasing member 6 is, but not limited to, a compression spring that has two ends respectively abutting against the abutment member 3 and the locking member 4. Particularly, the two ends of the biasing member 6 are respectively sleeved on the support pillar 315 of the abutment member 3 and the support pillar 414 of the locking member 4, and are respectively abutted against the abutment member 3 and the upper rod body 413 of the locking member 4.

Referring to FIGS. 2, 3, 4, and 6, the assembling of the locking mechanism 140 and the mounting of the locking mechanism 140 onto the frame 121 are exemplified as follows. First, the positioning post 314 of the sleeve shell 31 and the positioning post 326 of the handle rod 32 of the abutment member 3 are respectively aligned with the positioning holes 125 of the side plate 123. Next, the abutment member 3 is placed to abut against the side plate 123 such that the positioning posts 314, 326 are respectively engaged in the positioning holes 125. Then, each of the screws 8 is inserted into a corresponding one of the through holes 124 and is threaded with a corresponding one of the corresponding nuts 7, so as to fasten the abutment member 3 to the side plate 123. Then, the biasing member 6 is placed in the accommodating space 319 of the abutment member 3 such that one end of the biasing member 6 is sleeved on the support pillar 315. Subsequently, the retaining rod 41 of the locking member 4 is placed in the accommodating space 319 of the abutment member 3 such that the pivot hole 410 of the retaining rod 41 is aligned with the shaft holes 316 of the side walls 316 and such that another end of the biasing member 6 is sleeved on the support pillar 414. At this time, the engaging portion 412 of the locking member 4 is located below the sleeve 312 of the abutment member 3. Finally, the shaft 5 is inserted through the shaft hole 316 of the abutment member 3 and the pivot hole 410 of the locking member 4, thereby completing the assembly of the locking mechanism 140 and the installation of the locking mechanism 140 onto the frame 121. Since the locking mechanism 140 has fewer components, the assembly and the installation of the locking mechanism 140 are simple and convenient. The locking mechanism 140 has a simple and compact structure, thereby being more space-efficient and reducing manufacturing cost thereof.

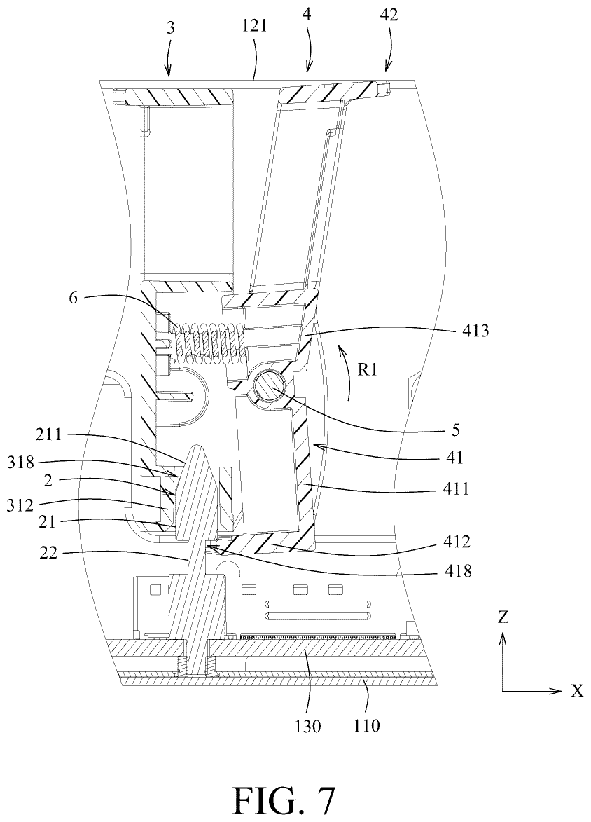

Referring to FIGS. 2, 6, and 7, the locking of the first electronic component 120 onto the second electronic component 130 by the locking mechanism 140 is exemplified as follows. First, the frame 121 of the first electronic component 120 is aligned with the housing 110 such that the first electronic component 120 is positioned above an intended installation position. At this time, the limiting hole 318 of the abutment member 3 is aligned with the head 21 of the positioning post 2. Next, the first electronic component 120 is moved downward, causing the locking mechanism 140 (except the positioning post 2 that is mounted on the second electronic component 130) to move downward together with the first electronic component 120. During the downward movement of the first electronic component 120, the head 21 of the positioning post 2 first enters the engaging slot 418 of the engaging portion 412, thereby bringing the engaging portion 412 into contact with the outer taper end surface 211 of the head 21. The outer taper end surface 211 applies a lateral force to the engaging portion 412 to push the locking member 4 to rotate relative to the abutment member 3 about the shaft 5 in a first rotating direction (R1) (see FIG. 7). As the locking member 4 rotates in the first rotating direction (R1), the upper rod body 413 of the retaining rod 41 pushes the biasing member 6 toward the abutment member 3, thereby causing the biasing member 6 to be deformed and to store a restoring force. Subsequently, the head 21 of the positioning post 2 enters the limiting hole 318 of the sleeve 312. When a positional deviation of the frame 121 occurs with respect to an imaginary plane extending in the first horizontal direction (X) and the second horizontal direction (Y), the sleeve 312 comes into contact with the outer taper end surface 211 of the head 21 and slides downward along the outer taper end surface 211, such that the sleeve 312 is gradually guided by the outer taper end surface 211 to correct the positional deviation, thereby allowing the head 21 to be properly inserted into the limiting hole 318. When the engaging portion 412 moves away from the outer taper end surface 211, the locking member 4 stops rotating. Thereafter, the abutment member 3 and the locking member 4 are continuously moved downward relative to the positioning post 2.

Referring to FIGS. 7 and 8, when the engaging portion 412 of the locking member 4 is moved downward to a position away from the head 21, the restoring force of the biasing member 6 is applied to the upper rod body 413 to push the upper rod body 413 back, thereby causing the locking member 4 to rotate in a second rotating direction (R2) (see FIG. 8) opposite to the first rotating direction (R1) about the shaft 5 relative to the abutment member 3. Meanwhile, the connectable circuit board 122 of the first electronic component 120 is connected to the second electronic component 130. When the locking member 4 is rotated to the locking position, further rotation is prevented as the engaging portion 412 is engaged with the neck 22, thereby automatically locking the locking member 4 onto the positioning post 2. Thus, the locking mechanism 140 automatically locks the first electronic component 120 onto the second electronic component 130.

By virtue of the biasing member 6 disposed to bias the upper rod body 413 of the locking member 4, the locking member 4 is retained in the locking position. Accordingly, the locking member 4 is securely locked onto the positioning post 2, thereby preventing the locking member 4 from being easily detached from the neck 22 of the positioning post 2 due to vibration or external forces. Moreover, when the locking member 4 is in the locking position, the operating lever 42 of the locking member 4 is spaced apart from the handle rod 32 of the abutment member 3, thereby forming an included angle (A) therebetween (see FIG. 8).

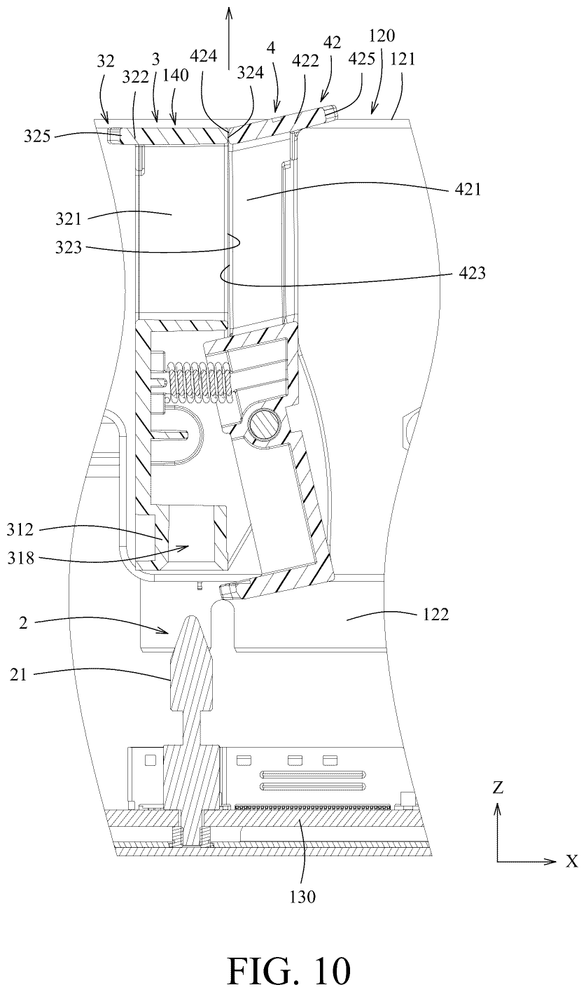

Referring to FIGS. 9 and 10, the unlocking of the locking member 4 and the removal of the first electronic component 120 from the second electronic component 130 are exemplified as follows. First, the first force-receiving surface 325 of the transverse portion 322 of the abutment member 3 and the second force-receiving surface 425 of the trigger portion 422 of the locking member 4 are respectively pressed by the user's two fingers. Since the locking member 4 is pivotally connected to the abutment member by the shaft 5, pressing of the second force-receiving surface 425 causes the locking member 4 to rotate relative to the abutment member 3 about the shaft 5 in the first rotating direction (R1). During the rotation of the locking member 4 in the first rotating direction (R1), the engaging slot 418 of the engaging portion 412 gradually moves from the neck 22 of the positioning post 2, the operating lever 42 gradually approaches the handle rod 32 of the abutment member 3, and the biasing member 6 is pressed by the upper rod body 413 of the retaining rod 41 and is deformed.

When the locking member 4 is rotated to the unlocking position, further rotation is prevented as the first inclined abutment surface 423 of the inclined portion 421 abuts against the upright abutment surface 323 and the second inclined abutment surface 424 of the trigger portion 422 abuts against the transverse abutment surface 324, such that the locking member 4 is limited by the handle rod 32 in the unlocking position. At this time, the locking member 4 is completely separated from the neck 22. Then, the first force-receiving surface 325 of the transverse portion 322 and the second force-receiving surface 425 of the trigger portion 422 are pulled upward by the user, such that the locking mechanism 140 (except the positioning post 2 that is mounted on the second electronic component 130) is moved upward with the first electronic component 120. When the limiting hole 318 of the sleeve 312 of the abutment member 3 is moved away from the head 21 of the positioning post 2, and the connectable circuit board 122 of the first electronic component 120 is separated from the second electronic component 130, the unlocking of the locking member 4 and the removal of the first electronic component 120 from the second electronic component 130 are completed.

By virtue of the abutment between the upright abutment surface 323 and the first inclined abutment surface 423, and the abutment between the transverse abutment surface 324 and the second inclined abutment surface 424, the contact areas between the locking member 4 and the abutment member 3 are increased, thereby enhancing stability of the abutment between the locking member 4 and the abutment member 3. In addition, the locking member 4 may be driven to the unlocking position simply by pressing the first force-receiving surface 325 and the second force-receiving surface 425, and the first electronic component 120 may be removed from the second electronic component 130 simply by pulling up the handle rod 32 and the operating lever 42, which are abutted against each other to form a stable lifting structure. Accordingly, the user may conveniently and quickly complete the unlocking of the locking member 4 and the removal of the first electronic component 120 from the second electronic component 130. The above-stated operations conform to ergonomics and have fewer steps, thereby further enhancing operability of the locking mechanism 140.

Referring to FIG. 8, for example, when the frame 121 is subjected to an upward external force in the vertical direction (Z), the upward external force is transmitted to the abutment member 3 so that the shaft 5 is pulled upwardly. Since the shaft 5 is spaced apart from the beveled surfaces 419 of the engaging portion 412 in the first horizontal direction (X), a torque in the same direction as the first rotating direction (R1) (as shown in FIG. 7) is generated when the shaft 5 is pulled upwardly due to the upward external force. The torque causes the annular lower surface 212 to apply a counterforce opposite to the upward external force on the beveled surfaces 419. The counterforce causes the beveled surfaces 419 to rotate toward the annular lower surface 212. When the beveled surface 419 is rotated to be horizontal, the beveled surface 419 abuts against the annular lower surface 212 in a surface-contact manner, thereby achieving a balanced stationary state, and thereby preventing the engaging slot 418 of the locking member 4 from being disengaged from the neck 22. Thus, the locking member 4 may be prevented from being inadvertently driven to the unlocking position, even when subjected to external forces caused by dropping or incorrect operation, thereby enhancing the stability of the locking.

It should be noted that the locking mechanism 140 of this embodiment may be implemented differently depending on actual requirements.

In some embodiments, the handle rod 32 of the abutment member 3 is configured such that the upright abutment surface 323 of the upright portion 321 abuts against the first inclined abutment surface 423 of the inclined portion 421 of the operating lever 42.

In some embodiments, the handle rod 32 of the abutment member 3 is configured such that the transverse abutment surface 324 of the transverse portion 322 abuts against the second inclined abutment surface 424 of the trigger portion 422 of the operating lever 42.

In summary, the locking mechanism 140 of this embodiment is composed of fewer components, making its assembly and installation onto the frame 121 simple and convenient. In addition, the locking mechanism 140 has a simple and compact structure, thereby being more space-efficient and reducing manufacturing cost thereof. The locking member 4 and the abutment member 3 of the locking mechanism 140 respectively provide automatic locking and blind insertion functions, thereby enhancing operability, operational speed, and efficiency of assembly and locking processes. The unlocking of the locking member 4 and the removal of the first electronic component 120 from the second electronic component 130 may be conducted sequentially and quickly by simply pressing and pulling up the first force-receiving surface 325 and the second force-receiving surface 425. This improves the convenience, operational speed, and efficiency of the unlocking and removal processes, thereby achieving the object of this disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A locking mechanism for removably locking a first electronic component to a second electronic component, comprising:
a positioning post adapted to be mounted on the second electronic component and having a neck;
a locking member adapted to be movably connected to the first electronic component, and including an engaging portion and a trigger portion; and
a biasing member disposed for biasing said locking member to retain said locking member in a locking position where said engaging portion is engaged with said neck;
wherein said trigger portion of said locking member is operable for driving said locking member to move away from the locking position to disengage said engaging portion from said neck and to deform said biasing member.

2. The locking mechanism as claimed in claim 1, wherein:
said positioning post further has a head that is connected to said neck;
said locking mechanism further comprises an abutment member that is adapted to be mounted on the first electronic component and that is sleeved removably on said head, and a shaft that is mounted to said abutment member and said locking member such that said locking member is connected to said abutment member and such that said locking member is pivotable about said shaft relative to said abutment member; and
said engaging portion of said locking member is located below said shaft, and said trigger portion of said locking member is located above said shaft.

3. The locking mechanism as claimed in claim 1, wherein:
said locking mechanism further comprises an abutment member that is adapted to be mounted on the first electronic component, that is sleeved removably on said positioning post, and that includes a handle rod;
said locking member is pivotably connected to said abutment member, and includes an operating lever that extends obliquely relative to said handle rod and that has said trigger portion;
said operating lever is spaced apart from said handle rod when said locking member is in the locking position; and
said trigger portion of said operating lever is operable for driving said locking member to move away from the locking position to an unlocking position where said engaging portion is disengaged from said neck, where said biasing member is deformed, and where said operating lever abuts against said handle rod.

4. The locking mechanism as claimed in claim 3, wherein said handle rod has an upright portion and a transverse portion that protrudes transversely from a top end of said upright portion, said operating lever further having an inclined portion, said trigger portion protruding transversely from a top end of said inclined portion, said handle rod being configured such that said upright portion abuts against said inclined portion of said operating lever when said locking member is in the unlocking position, and such that said transverse portion abuts against said trigger portion of said operating lever when said locking member is in the unlocking position.

5. The locking mechanism as claimed in claim 4, wherein said upright portion of said handle rod has an upright abutment surface, and said transverse portion of said handle rod has a transverse abutment surface that is connected to said upright abutment surface, and a first force-receiving surface that is opposite to said transverse abutment surface, said inclined portion of said operating lever having a first inclined abutment surface for abutting against said vertical abutment surface when said locking member is in the unlocking position, said trigger portion having a second inclined abutment surface for abutting against said horizontal abutment surface when said locking member is in the unlocking position, and a second force-receiving surface that is opposite to said second inclined abutment surface.

6. The locking mechanism as claimed in claim 3, wherein said handle rod has an upright portion and a transverse portion that protrudes transversely from a top end of said upright portion, said operating lever further having an inclined portion, said trigger portion protruding transversely from a top end of said inclined portion, said handle rod being configured such that said upright portion abuts against said inclined portion of said operating lever when said locking member is in the unlocking position.

7. The locking mechanism as claimed in claim 6, wherein said upright portion of said handle rod has an upright abutment surface, said inclined portion of said operating lever having a first inclined abutment surface for abutting against said vertical abutment surface when said locking member is in the unlocking position.

8. The locking mechanism as claimed in claim 3, wherein said handle rod has an upright portion and a transverse portion that protrudes transversely from a top end of said upright portion, said operating lever further having an inclined portion, said trigger portion protruding transversely from a top end of said inclined portion, said handle rod being configured such that said transverse portion abuts against said trigger portion of said operating lever when said locking member is in the unlocking position.

9. The locking mechanism as claimed in claim 8, wherein said transverse portion of said handle rod has a transverse abutment surface, said trigger portion having a second inclined abutment surface for abutting against said horizontal abutment surface when said locking member is in the unlocking position.

10. The locking mechanism as claimed in claim 1, further comprising an abutment member that is adapted to be mounted on the first electronic component, said abutment member including a sleeve shell that is sleeved removably on the positioning post, and a handle rod that protrudes from a top end of said sleeve shell, said handle rod and said sleeve shell cooperatively defining a first wiring channel, said locking member including a retaining rod that is pivotably connected to said sleeve shell, and an operating lever that protrudes from a top end of said retaining rod, said retaining rod having said engaging portion, said operating lever having said trigger portion, said retaining rod and said operating lever cooperatively defining a second wiring channel.

11. The locking mechanism as claimed in claim 10, wherein:
said first wiring channel extends in a horizontal direction and has two first end openings opposite to each other in the horizontal direction, and a first side opening located between said first end openings; and
said second wiring channel extends in the horizontal direction and has two second end openings opposite to each other in the horizontal direction, and a second side opening located between said second end openings.

12. The locking mechanism as claimed in claim 10, wherein:
each of said first wiring channel and said second wiring channel extends in a horizontal direction;
said handle rod is inverted L-shaped and has a upright portion that protrudes from a top end of said sleeve shell and that is adjacent to a lateral side of said sleeve shell, and a transverse portion that protrudes transversely from a top end of said upright portion; and
said operating lever is inverted L-shaped and has an inclined portion that protrudes from a top end of said retaining rod and that is adjacent to a lateral side of said retaining rod, said trigger portion protruding transversely from a top end of said inclined portion.

13. The locking mechanism as claimed in claim 1, further comprising an abutment member that is adapted to be mounted on the first electronic component and that is sleeved removably on said positioning post, said locking member being pivotably connected to said abutment member, said biasing member being a compression spring that has two ends respectively abutting against said abutment member and said locking member.

14. The locking mechanism as claimed in claim 1, wherein:
said locking mechanism farther comprises an abutment member that is adapted to be mounted on the first electronic component, that is sleeved removably on said positioning post, and that includes a handle rod;
said locking member is pivotably connected to said abutment member and includes an operating lever that has said trigger portion;
said operating lever is spaced apart from said handle rod when said engaging portion is in the locking position; and
said trigger portion of said operating lever is operable for driving said locking member to move away from the locking position to an unlocking position where said engaging portion is disengaged from said neck and where said operating lever abuts said handle rod.

15. The locking mechanism as claimed in claim 1, further comprising an abutment member that is adapted to be mounted on the first electronic component, that is sleeved removably on said positioning post, and that defines a first wiring channel, said locking member being pivotably connected to said abutment member and forming a second wiring channel.

16. An electronic device comprising a first electronic component, a second electronic component, and a locking mechanism as claimed in claim 1 for removably locking said first electronic component to said second electronic component.
